(19) United States
(12) Patent Application Publication
(10) Pub. No.: US 2024/0332045 A1
(43) Pub. Date: Oct. 3, 2024

(54) OPTICAL HEATING APPARATUS AND LIGHT SOURCE UNIT

(71) Applicant: Ushio Denki Kabushiki Kaisha, Tokyo (JP)

(72) Inventors: Kazumasa YOSHIOKA, Tokyo (JP); Shinji TANIGUCHI, Tokyo (JP)

(73) Assignee: Ushio Denki Kabushiki Kaisha, Tokyo (JP)

(21) Appl. No.: 18/622,319

(22) Filed: Mar. 29, 2024

(30) Foreign Application Priority Data
Mar. 30, 2023 (JP) 2023-055225

(51) Int. Cl. H01L 21/67; H01L 33/00

(52) U.S. Cl. CPC H01L 21/67115; H01L 33/0095

(57) ABSTRACT

Provided is an optical heating apparatus that allows high flexibility in setting an in-plane heating condition for a processing target substrate. The optical heating apparatus includes: a chamber; a supporter to support the processing target substrate; a light source unit including a plurality of heating groups being configured to emit light; and a controller to control electricity supplied to each of the plurality of the heating groups. One of the processing target substrate and the light source unit is configured to rotate relative to an other on a rotation axis. The plurality of the heating groups each include a plurality of light sources, and a nth and (n+1)th circular rotation loci partially overlap each other. The nth and (n+1)th circular rotation loci are drawn by virtual rotation of the light emission region of each light source belonging to a nth and (n+1)th heating group around the rotation axis.

### TECHNICAL FIELD

The present invention relates to an optical heating apparatus and a light source unit.

### BACKGROUND ART

A semiconductor production process includes various heat treatments applied to a processing target substrate such as a semiconductor wafer, including depositing, oxidizing and diffusing, reforming, or annealing. These treatments are often executed in accordance with a heat treatment method through light irradiation enabling contactless treatment. Patent Document 1 below discloses an optical heating apparatus that includes light-emitting diodes (LEDs) arranged in high density to increase the temperature of a processing target substrate at high rate.

### PRIOR ART DOCUMENTS

### Patent Documents

Patent Document 1: JP-A-2016-58722

### SUMMARY OF THE INVENTION

### Problems to be Solved by the Invention

Conventionally, apparatuses designed to irradiate a processing target substrate with light for heating have been required to have the ability to make the temperature uniform across a surface (particularly a main surface) of the processing target substrate for uniform treatment throughout the processing target substrate. This is because the processing target substrate is cut into a plurality of pieces upon completion of a heat treatment process to produce a plurality of elements, and uniform treatment contributes to reduce in-plane variation and provide an improvement in yield. The “main surface” herein refers to one of surfaces constituting a plate-shaped object and having a much larger area than other surfaces.

In conventional optical heating apparatuses, light sources that irradiate the processing target substrate with light for heating (hereinafter referred to as “heating light” for convenience) are arranged in high density, as in the optical heating apparatus described in Patent Document 1, for example, to satisfactorily supply heat energy necessary for treatment of the processing target substrate. To make in-plane temperature of the processing target substrate uniform in the apparatus that includes light sources arranged in high density, in-plane heating condition set for the processing target substrate has varying the outputs from each light source irradiating the main surface of the processing target substrate with heating light. In this case, flexibility in setting the heating condition in relation to an in-plane direction of the processing target substrate depends on the size of the light sources. Since there is a certain limit to the design of the size of the light sources, the conventional optical heating apparatuses have a problem in terms of flexibility in setting in-plane heating conditions for the processing target substrate.

Meanwhile, semiconductor processes have diversified in recent years, and there are cases in which a chemical solution or a gas for treatment of the processing target substrate (hereinafter referred to as a “treatment solution” for convenience) is put into contact with the main surface of the processing target substrate. In this case, the processing target substrate that is put into contact with the treatment solution can cause a transfer of heat and a consequent fluctuation in temperature. A circumferential end side of the processing target substrate is more apt to radiate heat compared with a center side of the processing target substrate, and thus there is a case in which the circumferential end side is required to be irradiated with heating light at higher irradiance compared with the center side. Further, when the processing target substrate is treated while being rotated, an effect on the temperature of the processing target substrate depends on rotation speed of the processing target substrate. In this way, the in-plane heating condition for the processing target substrate differs depending on the process applied to the processing target substrate.

However, if treatment apparatuses are individually introduced for each different process, a vast amount of introduction costs and vast space for the disposition of the apparatuses are needed. Hence, an optical heating apparatus that allows high flexibility in setting an in-plane heating condition for a processing target substrate is desired in order to be compatible with a plurality of processes.

In view of the above problem, it is an object of the present invention to provide an optical heating apparatus that allows high flexibility in setting an in-plane heating condition for a processing target substrate.

### Means for Solving the Problems

An optical heating apparatus according to the present invention includes: a chamber to accommodate a processing target substrate that is subject to heating; a supporter to support the processing target substrate inside the chamber; a light source unit including a plurality of heating groups arranged so as to face a main surface of the processing target substrate supported by the supporter, the plurality of the heating groups being configured to emit light for heating to the main surface; and a controller to control electricity supplied to each of the plurality of the heating groups, wherein one of the processing target substrate and the light source unit is configured to rotate relative to an other of the processing target substrate and the light source unit on a rotation axis passing through the main surface of the processing target substrate in a direction of normal to the main surface, the plurality of the heating groups each include a plurality of light sources that are at a substantially identical distance from the rotation axis, and an nth circular rotation locus drawn by virtually rotation of a light emission region of each of the light sources belonging to an nth heating group around the rotation axis and an (n+1)th circular rotation locus drawn by virtually rotation of a light emission region of each of the light sources belonging to an (n+1)th heating group that is nearer to the rotation axis than the nth heating group around the rotation axis partially overlap each other as viewed along the rotation axis.

In the optical heating apparatus described above, the plurality of the light sources arranged so as to face the main surface of the processing target substrate irradiate the processing target substrate with heating light. The light sources that “are arranged”, which is used herein, refer to LED devices that are placed on an LED substrate if the light source is an LED device, for example, or lamps that are attached to an arbitrary surface if the light source is a lamp.

In the present specification, the expression “the plurality of the light sources are at a substantially identical distance from the rotation axis” indicates that a difference in distance between each light source and the rotation axis is within or equal to ±1% of an average value. This is intended to provide tolerance of an error in the arrangement of light sources in a radial direction of a circle centered on the rotation axis.

The “light emission region” refers to an area through which heating light is substantially emitted from each of the light sources, which are included in each of the heating groups, to the main surface of the processing target substrate in a direction in which the processing target substrate and the light sources are placed face-to-face. The “light emission region” will be described in detail later in the section “MODE FOR CARRYING OUT THE INVENTION”.

From the viewpoint of improvement of flexibility in setting a heating condition for the processing target substrate, the present inventors have arranged the light sources of the light source unit, which irradiate the processing target substrate with heating light, by organizing the light sources into the plurality of the heating groups. At this time, the processing target substrate is heated while one of the processing target substrate and the light source unit is rotating on the rotation axis relative to the other of the processing target substrate and the light source unit to improve uniformity in temperature across the processing target substrate in a circumferential direction. In other words, with the processing target substrate rotating on the rotation axis relative to the light source unit, the processing target substrate is irradiated uniformly in the circumferential direction with the heating light emitted through the light emission regions from the light sources belonging to each of the heating groups.

After diligent research, the inventors found that, in the light source unit, a number of heating groups can be arranged in the radial direction of the substrate to be processed by arranging the nth circular rotation locus so that it partially overlaps the (n+1)th circular rotation locus in view along the axis of rotation. In this, the nth circular rotation locus is drawn by virtual rotation of the light emission region of each light source belonging to the nth heating group around the rotation axis. The (n+1)th circular rotation locus is drawn by virtual rotation of the light emission region of each light source belonging to the (n+1)th heating group around the rotation axis. The (n+1)th heating group is next closer to the rotation axis than the nth heating group. Similarly to the “light emission region”, a process for drawing the circular rotation locus by virtually rotating the light emission region around the rotation axis will be described in detail in the section “MODE FOR CARRYING OUT THE INVENTION”.

The configuration described above allows a larger number of the heating groups to be arranged in the radial direction compared with a case in which the light sources are placed side by side on a shared straight line in the radial direction. The arrangement of a larger number of the heating groups in the radial direction makes it possible to set a condition for irradiation with heating light more finely. In other words, the configuration described above improves flexibility in setting a heating condition for the processing target substrate in the optical heating apparatus.

The heating groups each include a plurality of the light sources that are at a substantially identical distance from the rotation axis. In other words, a plurality of the light sources that are at a substantially identical distance from the rotation axis are arranged separately from each other in the circumferential direction. This makes it possible to increase an amount of irradiation of the processing target substrate with heating light in the circumferential direction without making a size of the light source larger, for example. This suppresses an increase in the size of the light emission region in the radial direction of the rotation axis and thus allows a larger number of the heating groups to be arranged in the radial direction. This contributes to improve flexibility in setting a heating condition.

It is also within the scope of the invention if the light source unit includes an auxiliary light source separate from the heating group.

In the optical heating apparatus described above, an overlapping area where the nth circular rotation locus and the (n+1)th circular rotation locus overlap each other as viewed along the rotation axis preferably accounts for at least 50% of and more preferably accounts for at least 75% of an area of the (n+1)th circular rotation locus. An increase in the size of the overlapping area of the rotation loci allows a larger number of the heating groups to be arranged in the radial direction of the processing target substrate.

In the optical heating apparatus described above, a number of the light sources belonging to the nth heating group may be greater than or equal to a number of the light sources belonging to the (n+1)th heating group.

As described above, a circumferential end side of the processing target substrate is more apt to radiate heat compared with a center side of the processing target substrate. Hence, from the viewpoint of increasing an integrated irradiation dose of the heating light radiated to the substrate during one rotation, the number of the light sources in the nth heating group is preferably greater than or equal to the number of the light sources belonging to the (n+1)th heating group that is located interior to the nth heating group.

In the optical heating apparatus described above, the light sources belonging to the (n+1)th heating group may be arranged between the light sources belonging to the nth heating group in a circumferential direction of a circle centered on the rotation axis.

The above configuration makes it easier to increase the area where the nth circular rotation locus and the (n+1)th circular rotation locus overlap each other and allows a larger number of the heating groups to be arranged in the radial direction of the processing target substrate. From the viewpoint of making it easier to design wires and other parts for supplying electricity to the light sources, all the light sources belonging to the (n+1)th heating group may be arranged consecutively between the light sources belonging to the nth heating group in the circumferential direction.

In the optical heating apparatus described above, the nth heating group and the (n+1)th heating group may each include a plurality of the light sources arranged unevenly on the circumference of a circle centered on the rotation axis.

The “uneven arrangement of the light sources on the circumference of a circle” means as follows: on condition that the circle is formed by passing through centers of the light emission regions of the light sources arranged on the circumference of the circle and a circular arc is formed by connecting together the centers of the light emission regions of the light sources in the circumferential direction of the circle, a length of the circular arc is less than or equal to 50% of the circumference of the circle.

According to the above configuration, the light source unit has areas in which the light sources belonging to the respective heating groups are unevenly arranged. This makes it easier to design wires and other parts for supplying electricity to the light sources.

In the optical heating apparatus described above, the plurality of the light sources may have a light guide member to guide the light for heating being emitted from each of the light sources and traveling in a direction that is not aimed at the processing target substrate into a path toward the processing target substrate.

The heating light is emitted from the light emission regions of the light sources while having a certain tendency to spread. Thus, the part of the heating light travels in a direction that is not aimed at the processing target substrate. In response to this, the above configuration reduces a proportion of the heating light traveling in a direction that is not aimed at the processing target substrate. This makes it possible to efficiently irradiate the processing target substrate with the heating light.

In the optical heating apparatus described above, the plurality of the light sources may each include:
a plurality of LED devices; and a light guide member that surrounds the plurality of the LED devices as viewed along the rotation axis, the light guide member being configured to guide the light for heating being emitted from each of the light sources and traveling in a direction that is not aimed at the processing target substrate into a path toward the processing target substrate.

In the optical heating apparatus described above, the light guide member of one of the plurality of the light sources may be disposed so as to be separated from the light guide member of an other of the plurality of the light sources.

In the optical heating apparatus described above, the plurality of the light sources may have a substantially common arrangement of the plurality of the LED devices and a substantially common shape of the light guide member.

The arrangement of the LED devices and the shape of the light guide member, which are included in each of the light sources, are substantially common. This makes it easier to manufacture a plurality of the light sources. Therefore, the above configuration reduces costs for manufacturing the light source unit for the optical heating apparatus and is thus preferable.

In the optical heating apparatus described above, the light source unit may include an auxiliary light source disposed on the rotation axis, and the auxiliary light source may have a larger number of the LED devices than the plurality of the light sources each have.

Since a plurality of light sources cannot be disposed of on the rotation axis, it is difficult in some cases to increase an irradiation dose of the heating light radiated to a part of the processing target substrate through which the rotation axis passes. In view of this, an auxiliary light source may be disposed of on the rotation axis. Further, when the light sources and the auxiliary light source include LED devices, the number of the LED devices arranged on the auxiliary light source, which is disposed on the rotation axis, may be greater than the number of the LED devices arranged on each of the light sources. The disposition of the auxiliary light source on the rotation axis means that the rotation axis is within the light emission region of the auxiliary light source, which is described later.

### Effect of the Invention

The technique of the present invention provides an optical heating apparatus that allows high flexibility in setting an in-plane heating condition for a processing target substrate.

### BRIEF DESCRIPTION OF THE DRAWINGS

FIG. 1 is a schematic cross-sectional side view of an optical heating apparatus.

FIG. 2 is a schematic perspective view showing a structure of a supporter in the optical heating apparatus shown in FIG. 1.

FIG. 3A is a drawing of a light source unit as viewed in a −Z direction.

FIG. 3B is a cross-sectional view of the light source unit taken along a line B-B in FIG. 3A.

FIG. 3C is an exploded perspective view showing an LED substrate and a light guide member.

FIG. 3D is an enlarged view showing light sources near a rotation axis in FIG. 3A.

FIG. 4A is a drawing showing light sources belonging to a first heating group through a sixth heating group and an auxiliary light source in the light source unit shown in FIG. 3A.

FIG. 4B is a drawing showing light sources belonging to a seventh heating group through a 12th heating group in the light source unit shown in FIG. 3A.

FIG. 5 is a drawing showing a distance between a light source belonging to each heating group and the rotation axis.

FIG. 6 is a conceptual diagram of a light emission region of a light source belonging to the first heating group and a light emission region of a light source belonging to the second heating group each virtually rotated around the rotation axis.

FIG. 7 is another drawing showing a relationship between the first heating group and the second heating group.

FIG. 8 is a schematic view showing a light source unit as a comparative example where light emission regions of light sources are arranged so as to be adjacent to each other side by side in an identical radial direction.

FIG. 9A is a drawing showing a relationship between arranged light sources belonging to respective heating groups in FIG. 4A.

FIG. 9B is another drawing showing a relationship between the first heating group and the second heating group of arranged light sources in FIG. 9A.

FIG. 10 is another drawing showing a relationship between arranged light sources belonging to respective heating groups in FIG. 4A.

FIG. 11 is a schematic block diagram showing a configuration of a controller.

FIG. 12A is a graph of a heating condition simulated for a processing target substrate on condition that electricity supplied to heating groups is controlled based on a control pattern shown in Table 2.

FIG. 12B is a graph of a heating condition simulated for a processing target substrate on condition that electricity supplied to heating groups is controlled based on a control pattern different from that in FIG. 12A.

FIG. 13 is a cross-sectional view showing another example of a through-hole provided in a light guide member, following the example of FIG. 3B.

FIG. 14A is a schematic view showing an example of another configuration of a light guide member, following the example of FIG. 3A.

FIG. 14B is a schematic view showing an example of another configuration of a light guide member, following the example of FIG. 3C.

FIG. 15A is a schematic cross-sectional side view of a modification of the optical heating apparatus.

FIG. 15B is a drawing of a light source unit in FIG. 15A as viewed from a first main surface of a substrate in the −Z direction, following the example of FIG. 3A.

FIG. 15C is an enlarged cross-sectional view showing a lamp that constitutes a light source.

FIG. 16 is a schematic view showing another example of arranged light sources in a light source unit.

### MODE FOR CARRYING OUT THE INVENTION

An embodiment of an optical heating apparatus according to the present invention will now be described with reference to the drawings. Note that each of the drawings described below is schematic illustration, and a dimensional ratio or the number of pieces in the drawings does not necessarily coincide with an actual dimensional ratio or the actual number of pieces.

### (Optical Heating Apparatus 1)

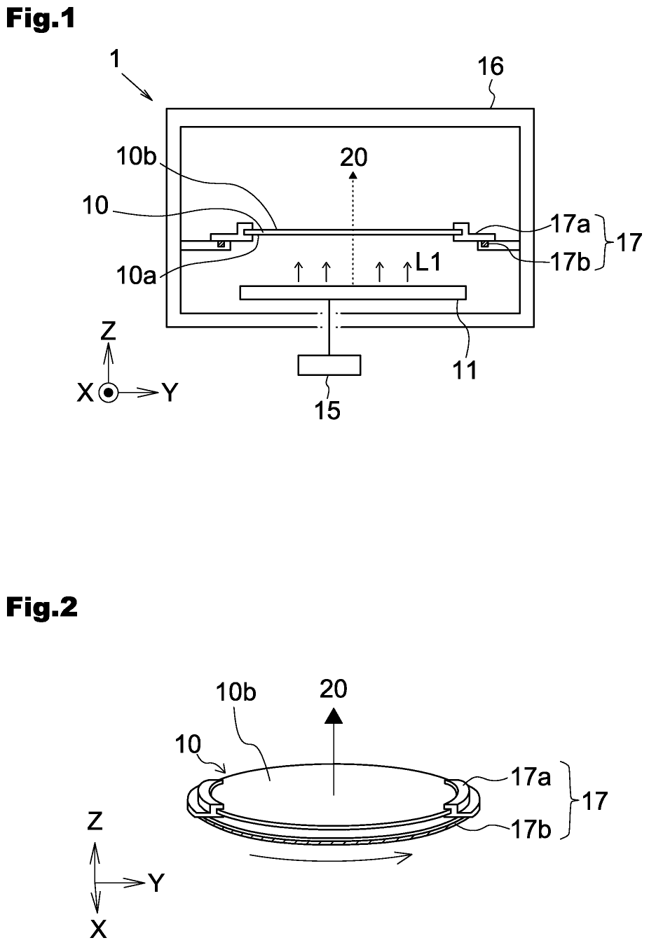

FIG. 1 is a schematic cross-sectional side view of an optical heating apparatus 1. As shown in FIG. 1, the optical heating apparatus 1 includes a chamber 16 to accommodate a processing target substrate 10 that is subject to heating, a supporter 17 to support the processing target substrate 10 inside the chamber 16, a light source unit 11, and a controller 15.

In the following description, an X-Y-Z coordinate system is referenced appropriately in which a plane parallel to a main surface of the processing target substrate 10 is defined as an X-Y plane, and a direction orthogonal to the main surface of the processing target substrate 10 is defined as a Z direction. When positive and negative directions are distinguished at the time of expressing directions, the directions are described with a positive or negative symbol, such as “+X direction” or “−X direction”. When the direction is expressed without distinguishing between positive and negative direction, the direction is simply described as “X direction”. Namely, in the present specification, when the direction is simply described as “X direction”, both “+X direction” and “−X direction” are included. The same applies to a Y direction and a Z direction.

### (Chamber 16)

The chamber 16, as shown in FIG. 1, accommodates the processing target substrate 10 and the light source unit 11 that irradiates a main surface on a −Z side of the processing target substrate 10 (hereinafter referred to as a “first main surface 10a” for convenience) with heating light L1. The chamber 16 has the supporter 17 to support the processing target substrate 10 such that the first main surface 10a of the processing target substrate 10 is irradiated with the heating light L1. A main surface on a +Z side of the processing target substrate 10 is a second main surface 10b for the convenience of description.

### (Supporter 17)

FIG. 2 is a schematic perspective view showing a structure of the supporter 17 in the optical heating apparatus 1 shown in FIG. 1. In an example shown in FIGS. 1 and 2, the supporter 17 includes a rotation rail 17b and a plurality of clamps 17a rotatable along the rotation rail. The processing target substrate 10 is clamped and supported by the clamps 17a. The clamps 17a rotate along the rotation rail 17b, and the processing target substrate 10 thereby rotates relative to the light source unit 11 on a rotation axis 20 passing through in a direction of normal to the second main surface 10b (the Z direction). In the present embodiment, the rotation axis 20 passes through a center of the processing target substrate 10. However, the scope of the present invention should not be limited, and the rotation axis 20 may or may not pass through the center of the processing target substrate 10.

### (Light Source Unit 11)

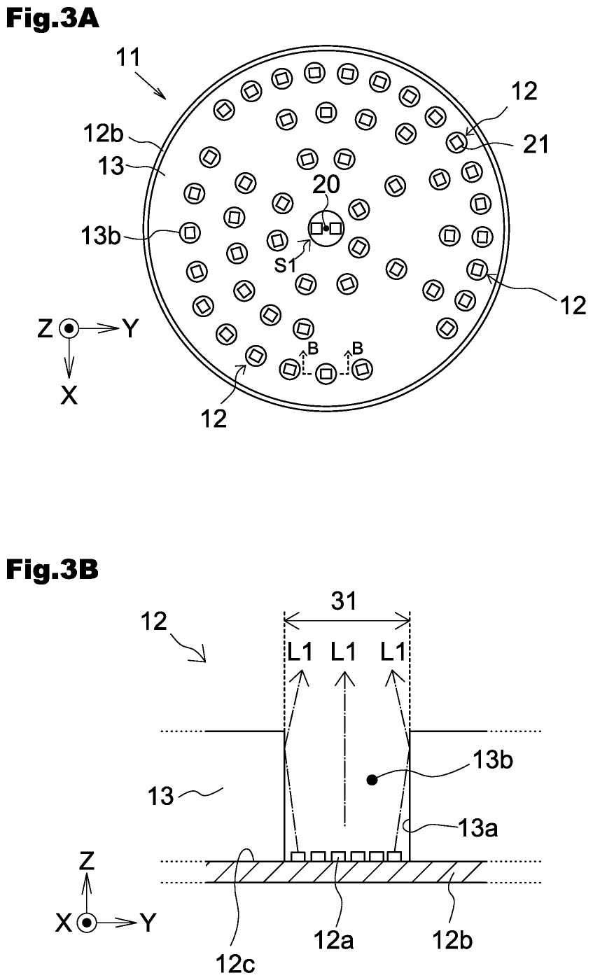

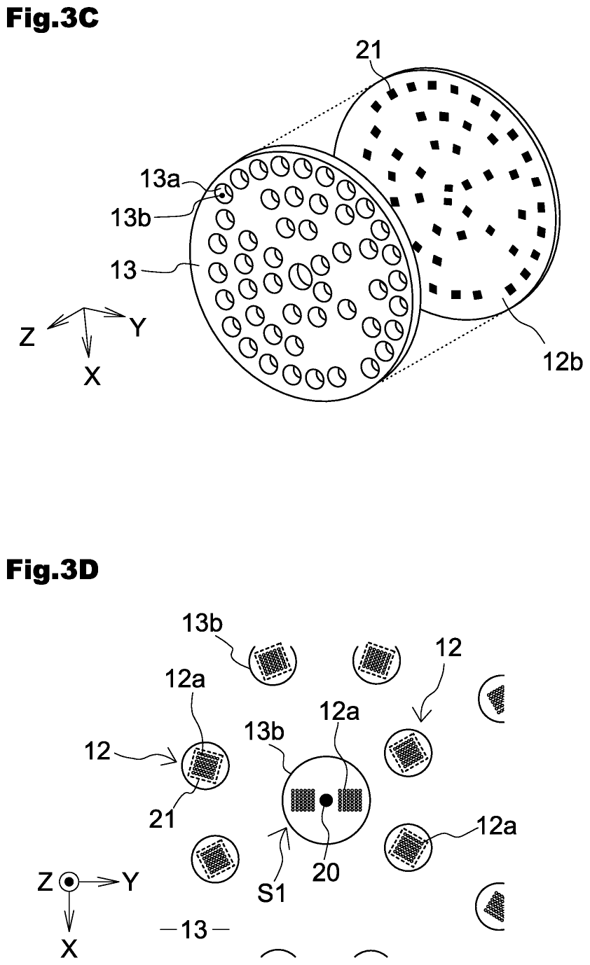

FIG. 3A is a drawing of the light source unit 11 as viewed in a −Z direction. FIG. 3B is a cross-sectional view of the light source unit 11 taken along a line B-B in FIG. 3A. FIG. 3C is an exploded perspective view showing an LED substrate 12b and a light guide member 13. FIG. 3D is an enlarged view showing a vicinity of the rotation axis 20 in FIG. 3A.

As shown in FIG. 3A, the light source unit 11 includes a plurality of light sources 12 to emit the heating light L1 and the light guide member 13. In FIG. 3A, illustration of LED devices 12a included in the light sources 12 is omitted, and a disposition region 21 described later is shown.

As shown in FIG. 3B, the light source 12 includes the LED substrate 12b, the LED devices 12a placed on the LED substrate 12b, and the light guide member 13. A placement surface 12c of the LED substrate 12b on which the LED devices 12a are placed faces the first main surface 10a of the processing target substrate 10 (refer to FIG. 1).

FIG. 3B schematically shows a mode of travel of the heating light L1 emitted from the LED devices 12a in the light source 12. As shown in FIG. 3B, the light guide member 13 guides the heating light L1 in a +Z direction by causing the heating light L1 to reflect off an inner surface (a reflecting surface 13a) of a through-hole 13b.

As shown in FIG. 3B, a light emission region 31 through which the heating light L1 is emitted is defined for each of the light sources 12. The “light emission region 31” described herein refers to a region through which the heating light L1 is substantially emitted in the Z direction when the light source unit 11 is viewed from the +Z side.

The heating light L1 emitted from the LED devices 12a travels while having a certain tendency to spread. On the other hand, when the light guide member 13 is disposed as shown in FIG. 3B, the heating light L1 reflects off the reflecting surface 13a of the light guide member 13, is thereby guided to the +Z side, and is radiated to the processing target substrate 10. Thus, the heating light L1 is substantially emitted from the through-hole 13b of the light guide member 13. In other words, in an example shown in FIG. 3B, an opening zone in an end face on the +Z side of the through-hole 13b provided in the light guide member 13 corresponds to the light emission region 31.

A case in which the light guide member 13 is not disposed is also within the scope of the present invention. In this case, an outer edge of the disposition region 21 for the LED devices 12a in the light source 12 corresponds to the light emission region 31 when the light source unit 11 is viewed from the first main surface 10a of the processing target substrate 10.

As shown in FIG. 3C, the light guide member 13 is a plate in which the through-holes 13b are provided in a plate-shaped member so as to correspond to places of the respective light sources 12. The plate-shaped member is made of a member that reflects the heating light L1. The through-hole 13b for one of the light sources 12 is disposed separately from the through-hole 13b for an other of the light sources 12. As described above, the inner surface of the through-hole 13b corresponds to the reflecting surface 13a.

The light guide member 13 is a plate, and the through-hole 13b is provided to correspond with the disposition region 21 for the LED devices 12a placed on the LED substrate 12b. As a result, the reflecting surfaces 13a readily surround the respective disposition regions 21 as viewed in the Z direction. This simplifies a production process for the light source unit 11. The light guide member 13 is made of, for example, a metal such as aluminum, aurum, copper, or rhodium.

In the present embodiment, as shown in FIG. 3D, 6×7 pieces, i.e., 42 pieces of the LED devices 12a, which are each surface-emitting and have a diameter of 0.5 mm, are arranged in each of the light sources 12. In other words, an area of the disposition region 21, which corresponds to an outer edge of a region in which the LED devices 12a are arranged, is 110 mm². A diameter of the through-hole 13b, which surrounds the LED devices 12a, is 20 mm. A diameter of the light guide member 13 is 33 cm.

The light sources 12 may have a substantially common arrangement of the LED devices 12a and a substantially common shape of a part of the light guide member 13. A “substantially common arrangement of the LED devices” indicates that the disposition regions 21 for the LED devices 12a in the light sources 12 have a common shape, and a difference among the areas of the disposition regions 21 is within or equal to ±5% of an average value. A “substantially common shape of a part of the light guide member” described herein indicates that the through-holes 13b in the light sources 12 have a common shape when the light source unit 11 is viewed in a direction of the normal to the first main surface 10a of the processing target substrate 10 (the Z direction), and a difference among areas of the opening zones is within or equal to ±5% of an average value. In this case, it is preferred that a difference in number of the LED devices 12a arranged in the light sources 12 is within or equal to ±10% of an average value.

In the present embodiment, the rotation axis 20 passes through a center of the first main surface 10a. Thus, from the viewpoint of increasing an irradiation dose of the heating light L1 radiated to a center area of the processing target substrate 10, an auxiliary light source S1 is disposed on the rotation axis 20. A larger number of the LED devices 12a may be arranged in the auxiliary light source S1 compared with the other light sources 12. More specifically, 6×7×2 pieces, i.e., 84 pieces of the LED devices 12a, which are twice the number of the LED devices 12a for the other light sources 12, are arranged in the auxiliary light source S1. A diameter of the through-hole 13b that surrounds the LED devices 12a is 35 mm.

The disposition of the auxiliary light source S1 on the rotation axis 20 described herein means that the rotation axis 20 is within the light emission region 31 for the auxiliary light source S1. The light emission region 31 for the light source 12 is described earlier with reference to FIG. 3B, and the same description can be given to the light emission region 31 for the auxiliary light source S1.

The number of the arranged LED devices 12a in the auxiliary light source S1, which is disposed on the rotation axis 20, may be equal to the number of the arranged LED devices in the other light sources 12. Further, the auxiliary light source S1 may be or may not be disposed on the rotation axis 20, and the scope of the present invention should not be limited.

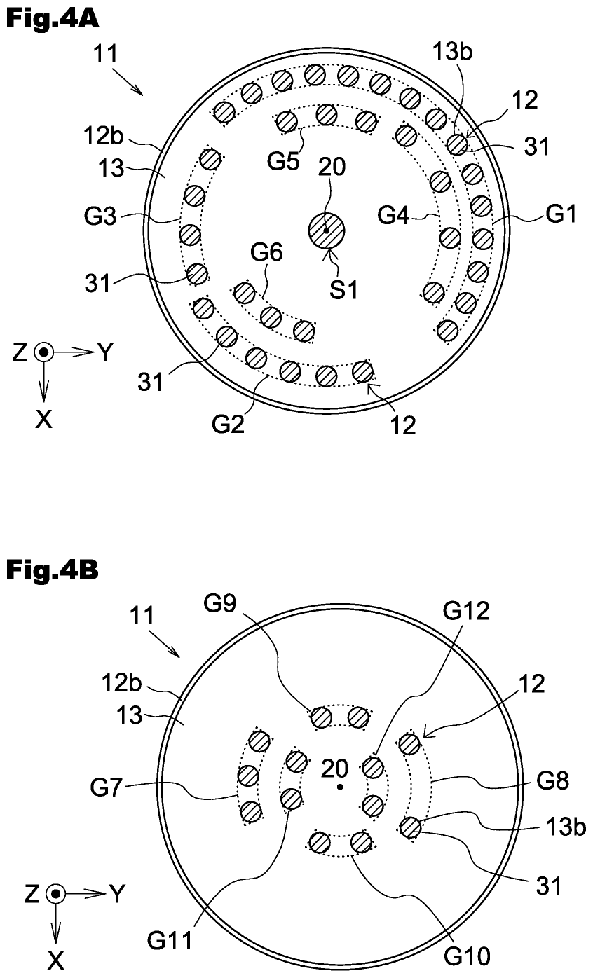

In the present embodiment, the light source unit 11 includes a first heating group G1 through a 12th heating group G12. FIG. 4A is a drawing showing the light sources 12 belonging to the first heating group G1 through a sixth heating group G6 and the auxiliary light source S1, which is disposed on the rotation axis 20, in the light source unit 11 shown in FIG. 3A. FIG. 4B is a drawing showing the light sources 12 belonging to a seventh heating group G7 through the 12th heating group G12. In FIGS. 4A and 4B, the light emission regions 31 for the light sources 12 and the auxiliary light source S1, which are described above with reference to FIG. 3B, are hatched by solid lines.

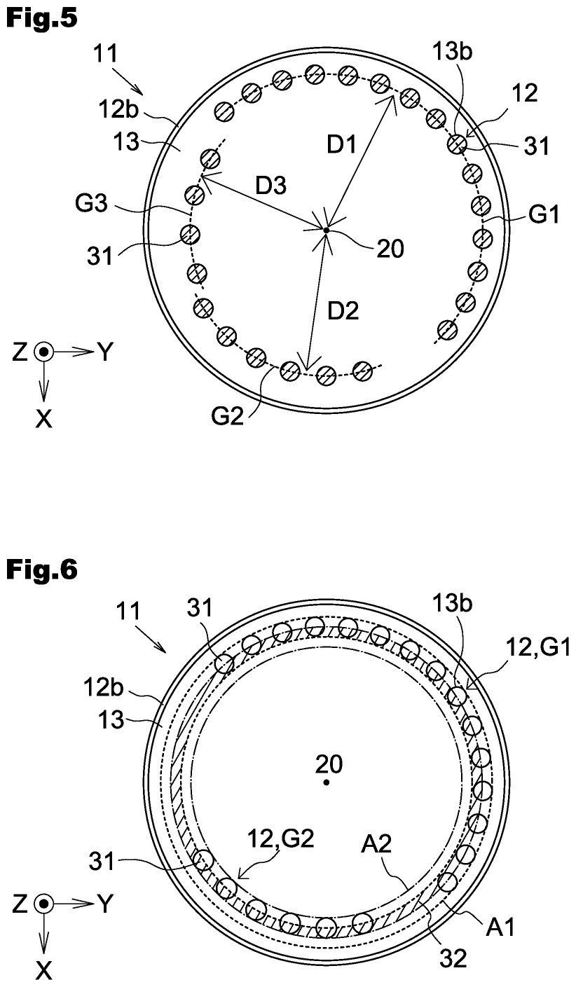

FIG. 5 is a drawing showing a distance between the light source 12 belonging to each heating group and the rotation axis 20. The distance means a distance between the rotation axis 20 and a center of the light emission region 31 for the light source 12 in a radial direction of the processing target substrate 10. In FIG. 5, only the light sources 12 belonging to the first heating group G1 through a third heating group G3 are illustrated for convenience of illustration, and distances (D1 to D3) between the centers of the respective light emission regions 31 and the rotation axis 20 are illustrated. As shown in FIG. 5, the heating groups (G1 to G3) each include a plurality of the light sources 12 that are at a substantially identical distance from the rotation axis 20. Specifically, the light sources 12 that are at the distance D1 from the rotation axis 20 constitute the first heating group G1. The same description can be given to a second heating group G2 and subsequent heating groups. The second heating group G2 is nearer to the rotation axis 20 compared with the light sources 12 belonging to the first heating group G1. In other words, in this case, the first heating group G1 corresponds to the nth heating group, and the second heating group G2 corresponds to the (n+1)th heating group.

Table 1 below shows a distance between the rotation axis 20 and the center of the light emission region 31 for the light source 12 belonging to each heating group in the radial direction of the processing target substrate 10, as well as the number of the light sources 12 belonging to each heating group. In Table 1, the auxiliary light source S1 disposed on the rotation axis 20 is also shown for convenience.

TABLE 1

| | G1 | G2 | G3 | G4 | G5 | G6 | G7 | G8 | G9 | G10 | G11 | G12 | S1 |
|---|---|---|---|---|---|---|---|---|---|---|---|---|---|
| Distance from Rotation Axis | 145 | 135 | 125 | 115 | 105 | 95 | 85 | 75 | 65 | 55 | 45 | 35 | 0 |
| (mm) | | | | | | | | | | | | | |
| Number of Light Sources (piece) | 15 | 6 | 4 | 4 | 3 | 3 | 3 | 2 | 2 | 2 | 2 | 2 | 1 |

As shown in Table 1, the (n+1)th heating group includes the light sources 12 that are nearer to the rotation axis 20 than the light sources of the nth heating group. In the present embodiment, the auxiliary light source S1 is disposed on the rotation axis 20. In this way, the light source unit 11 may include the auxiliary light source S1 aside from the heating groups that are each made up of a plurality of the light sources 12. The auxiliary light source S1 may be disposed at any place.

FIG. 6 is a conceptual diagram of the light emission region 31 for the light source 12 belonging to the first heating group G1 and the light emission region 31 for the light source 12 belonging to the second heating group G2 being each virtually rotated around the rotation axis 20. As shown in FIG. 6, the light emission region 31 for the light source 12 belonging to each heating group draws a circular rotation locus when being virtually rotated around the rotation axis 20. In FIG. 6, a circular rotation locus of the light emission region 31 for the light source 12 belonging to the first heating group G1 (hereinafter referred to as a “first rotation locus A1”) is indicated by broken lines, whereas a circular rotation locus of the light emission region 31 for the light source 12 belonging to the second heating group G2 (hereinafter referred to as a “second rotation locus A2”) is indicated by one-dot chain lines. Since the processing target substrate 10 rotates relative to the light source unit 11 on the rotation axis 20 as described above, it can be said that the heating light L1 is emitted from the circular rotation locus of each heating group toward the processing target substrate 10.

As shown in FIG. 6, the first rotation locus A1 and the second rotation locus A2 partially overlap each other as viewed in the Z direction. In FIG. 6, an overlapping area 32 where the rotation loci (A1, A2) overlap is hatched. In other words, in this example, the first rotation locus A1 corresponds to an nth rotation locus, and the second rotation locus A2 corresponds to an (n+1)th rotation locus.

In FIG. 6, a description is given by taking the first rotation locus A1 and the second rotation locus A2 as an example. The same description can be given to the third heating group G3 and subsequent heating groups. In the present invention, when a rotation locus is drawn by virtually rotating the light emission regions 31 of every heating group around the rotation axis 20, the light source unit 11 may include a heating group the rotation locus of which does not overlap the rotation locus of any other heating group.

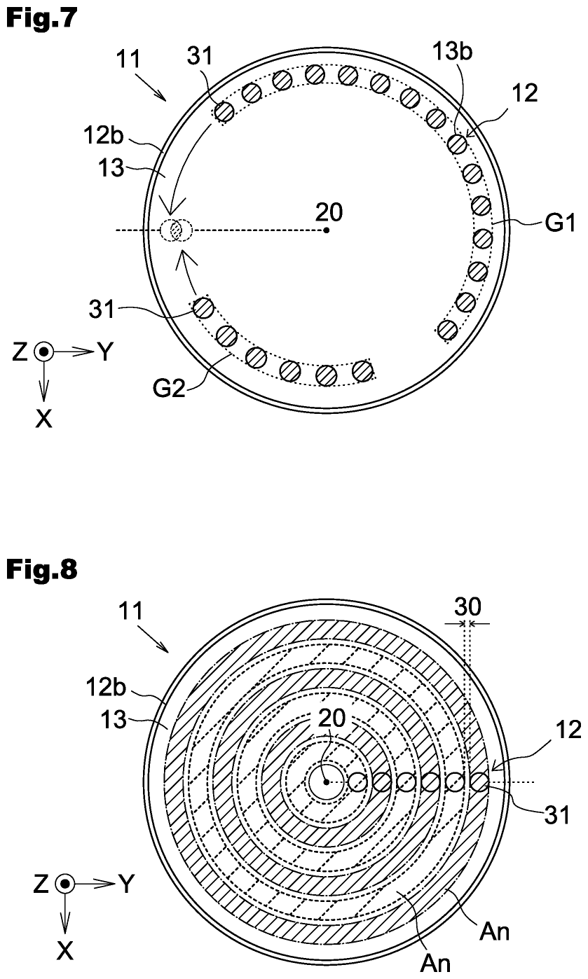

FIG. 7 is another drawing showing a relationship between the first heating group G1 and the second heating group G2. In the present embodiment, as shown in FIG. 7, the first rotation locus A1 and the second rotation locus A2 overlapping each other means that the light emission region 31 of the first heating group G1 and the light emission region 31 of the second heating group G2 partially overlap each other when the light emission regions 31 are virtually rotated around the rotation axis 20 and are aligned in an identical radial direction. In FIG. 7, an area where the light emission regions 31 overlap each other is hatched by broken lines.

There is a case in which a difference exists, for example, in shape among the parts of the light guide member 13 of the light sources 12 belonging to an identical heating group when the light emission regions 31 of the heating groups are virtually rotated and aligned in the radial direction (refer to FIG. 7). In this case, of the light sources 12 in the heating group, the opening zone of the through-hole 13b that is the largest in the radial direction in the part of the light guide member 13 of the light source 12 may be defined as the light emission region 31 of the heating group.

In an example shown in FIG. 6, the overlapping area 32 where the first rotation locus A1 and the second rotation locus A2 overlap accounts for at least 50% of an area of the second rotation locus A2. This point is also represented in FIG. 7 in which an area where the light emission regions 31 of the first heating group G1 and the second heating group G2 that are virtually rotated and aligned overlap each other makes up substantially 50% of the light emission region 31 of the second heating group G2 in the radial direction of the processing target substrate 10. As describe above, from the viewpoint of disposing as many heating groups as possible in the radial direction of the processing target substrate, the overlapping area 32 preferably accounts for a high proportion of the rotation locus of the heating group that is nearer to the rotation axis 20. However, in the present invention, the overlapping area 32 may account for any proportion of the rotation locus of the heating group that is nearer to the rotation axis 20.

As a comparative example to the configuration described in FIG. 6, FIG. 8 is a schematic view showing a light source unit 11 where the light emission regions 31 for the light sources 12 are arranged so as to be adjacent to each other side by side in an identical radial direction. The “adjacent to” described here indicates that a distance 30 at which the light emission regions 31 for the light sources 12 are separated from each other in the radial direction is less than or equal to 1 mm. FIG. 8, in a similar way to FIG. 6, shows a rotation locus An of the light emission region 31 for each light source 12 when the light emission region 31 is rotated around the rotation axis 20, on the assumption that the processing target substrate 10 rotating in a circumferential direction is irradiated with the heating light L1. The rotation loci An are hatched alternately by solid lines and broken lines in the radial direction for convenience of illustration. In FIG. 8, the light sources 12 arranged in the circumferential direction are omitted.

As shown in FIG. 8, in the case in which the light sources 12 are arranged side by side in an identical radial direction, the rotation locus An drawn by the light emission region 31 for a light source 12 through a rotation around the rotation axis 20 does not overlap the rotation locus An of another light source 12. Meanwhile, in the present embodiment, as described with reference to FIG. 6, the rotation locus of the light emission region 31 for a light source 12 virtually overlaps the rotation locus of the light emission region 31 for another light source 12 included in the heating group that is nearer to the rotation axis 20. This provides a larger number of the heating groups in the radial direction compared with the case (FIG. 8) in which the light sources 12 are placed side by side on a shared straight line in the radial direction. The arrangement of a larger number of the heating groups in the radial direction makes it possible to set an irradiation condition for the heating light L1 more finely. In other words, the configuration in FIG. 6 improves flexibility in setting a heating condition for the processing target substrate 10 compared with FIG. 8.

With reference back to FIG. 4A, the number of the light sources 12 belonging to the first heating group G1 is greater than or equal to the number of the light sources 12 belonging to the second heating group G2 (refer to Table 1 as well). As described above, a circumferential end side, i.e., an external side in the radial direction, of the processing target substrate 10 is more apt to radiate heat compared with a center side of the processing target substrate 10. Hence, it is preferred that the number of the light sources 12 arranged in the heating group on an external side in the radial direction be greater than or equal to the number of the light sources in the heating group on an internal side to increase an integrated irradiation dose of the heating light L1 radiated to the processing target substrate 10 during one rotation.

A conceivable way of increasing the integrated irradiation dose of the heating light L1 is to increase electricity supplied to the light source 12. However, it is feared that an increase in electricity supplied to the light source 12 might facilitate deterioration of the LED devices 12a, which are a component of the light source 12, or a lamp described later. Therefore, it is preferred that a plurality of the light sources 12 be arranged in each heating group and the rotation locus of the light emission region 31 virtually rotated includes the light emission regions 31 of the plurality of the light sources 12. This contributes to suppress electricity supplied to a single unit of the light source 12 and simultaneously increase the integrated irradiation dose of the heating light L1 radiated to the processing target substrate 10.

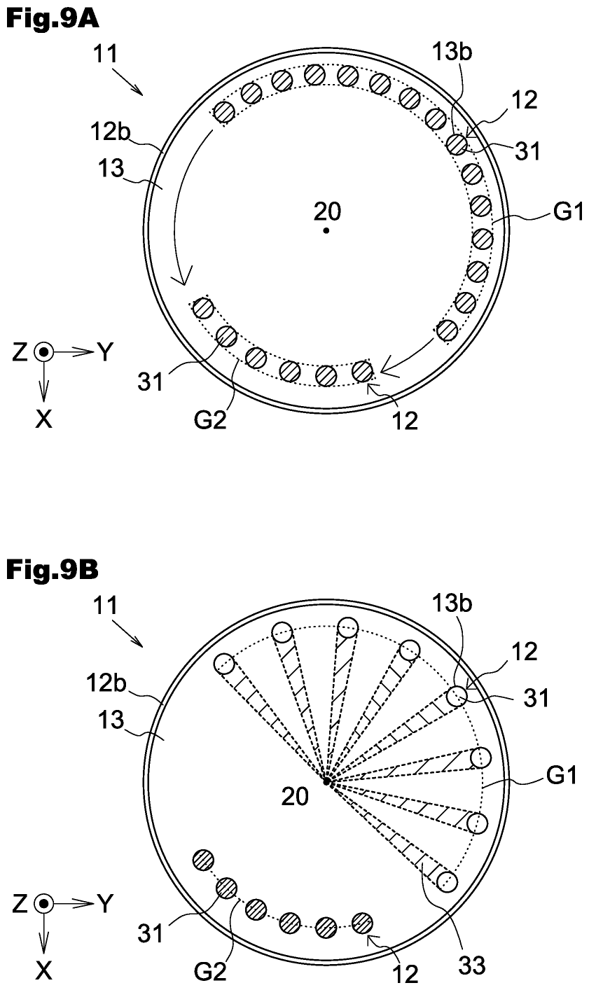

FIG. 9A is a drawing showing a relationship between the arranged light sources 12 belonging to respective heating groups in FIG. 4A. As shown in FIG. 9A, the light sources 12 belonging to the second heating group G2 are arranged between the light sources 12 belonging to the first heating group G1 in the circumferential direction. This configuration makes it easier to increase the overlapping area 32 where the first rotation locus A1 and the second rotation locus A2 overlap and allows a larger number of the heating groups to be arranged in the radial direction of the processing target substrate. In FIG. 9A, only the first heating group G1 and the second heating group G2 are shown, but the same applies to other heating groups such as the second heating group G2 and the third heating group G3 (refer to FIG. 4A).

With reference to FIG. 9B, an effect of the configuration described with FIG. 9A will be described in detail. FIG. 9B is another drawing showing a relationship between the first heating group G1 and the second heating group G2 of the arranged light sources in FIG. 9A. In FIG. 9B, some of the light sources 12 belonging to the first heating group G1 are omitted for convenience of illustration. As shown in FIG. 9B, the light sources 12 belonging to the second heating group G2 being arranged between the light sources 12 belonging to the first heating group G1 in the circumferential direction as described above, means that any of the light sources 12 belonging to the second heating group G2 is disposed outside a virtual area 33 that is formed by connecting the light emission region 31 for each light source 12 belonging to the first heating group G1 with the rotation axis 20 by two virtual tangent lines.

This configuration allows the light sources 12 belonging to the first heating group G1 and the light sources 12 belonging to the second heating group G2 to be disposed closer to each other in the radial direction. This increases the overlapping area 32 where the first rotation locus A1 and the second rotation locus A2 overlap and, as a result, allows a larger number of the heating groups to be arranged in the radial direction of the processing target substrate 10. Meanwhile, although illustrations are omitted, if the light emission region 31 for the light source 12 belonging to the second heating group G2 is disposed so as to overlap the virtual area 33, the light source 12 belonging to the first heating group G1 and the light source 12 belonging to the second heating group G2 are disposed more distant from each other in the radial direction, decreasing the overlapping area 32 where the first rotation locus A1 and the second rotation locus A2 overlap.

Hence, it is preferred that the light sources 12 belonging to the second heating group G2 be arranged between the light sources 12 belonging to the first heating group G1, in other words, outside the virtual areas 33, in the circumferential direction.

From the viewpoint of making it easier to design wires and other parts for supplying electricity to the light sources 12, it is preferred, as shown in FIG. 9A, that all the light sources 12 belonging to the second heating group G2 be arranged consecutively between the light sources 12 belonging to the first heating group G1.

In the present embodiment, the light emission region 31 has a circular shape, and thus the virtual area 33 is formed by the lines being tangent to the light emission region 31 and extending to the rotation axis 20. However, if the light emission region 31 has a polygonal shape, for example, the virtual area 33 may be formed by lines being tangent to a circumscribed circle of the light emission region 31 and extending to the rotation axis 20.

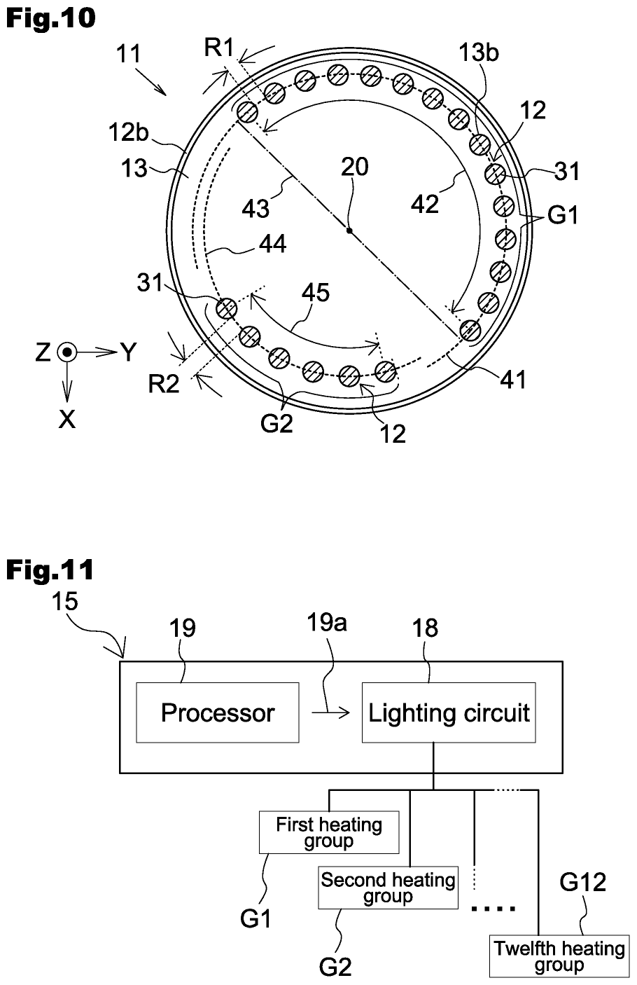

In the present embodiment, a plurality of the light sources 12 in each heating group are arranged unevenly on the circumference of a circle centered on the rotation axis 20. FIG. 10 is another drawing showing a relationship between the arranged light sources 12 belonging to respective heating groups in FIG. 4A. FIG. 10 shows a circle 41 formed by passing through centers of the light emission regions 31 for the light sources 12 belonging to the first heating group G1, a diameter 43 of the circle 41, and a circular arc 42 connecting together the centers of the light emission regions 31 for the light sources 12 belonging to the first heating group G1 in the circumferential direction of the circle 41. As shown in FIG. 10, a length of the circular arc 42 is less than or equal to 50% of the circumference of the circle 41. Part of the circle 41 is omitted for convenience of illustration.

FIG. 10 also shows a circle 44 formed by passing through centers of the light emission regions 31 for the light sources 12 belonging to the second heating group G2 and a circular arc 45 connecting together the centers of the light emission regions 31 for the light sources 12 belonging to the second heating group G2 in the circumferential direction of the circle 44. A length of the circular arc 45 is less than or equal to 50% of the circumference of the circle 44.

In this way, the light sources 12 are arranged unevenly in each of the heating groups adjacent to each other, thus making it easier to design wires and other parts for supplying electricity to the light sources 12.

More specifically, in the present embodiment, the light sources 12 belonging to the first heating group G1 are arranged such that a distance R1 between the adjacent light sources 12 in the first heating group G1 is less than or equal to 1% of the circumference of the circle 41 (refer to FIG. 10). Similarly, the light sources 12 belonging to the second heating group G2 are arranged such that a distance R2 between the adjacent light sources 12 in the second heating group is less than or equal to 2% of the circumference of the circle 44. In this way, from the viewpoint of arranging the light sources 12 unevenly, it is preferred that a distance between the light sources 12 belonging to a shared heating group in the circumferential direction be less than or equal to 5% of the circumference of a circle formed by passing through the centers of the light emission regions 31 for the light sources 12 in the same heating group.

### (Controller 15)

FIG. 11 is a schematic block diagram showing a configuration of the controller 15. As shown in FIG. 11, the controller 15 includes a lighting circuit 18 and a processor 19. The processor 19 sends a control signal 19a, which includes a power value supplied to the light sources 12 belonging to each heating group, to the lighting circuit 18. Based on the control signal 19a, the lighting circuit 18 controls individually electricity supplied to the light sources 12 belonging to the respective heating groups. In FIG. 11, one lighting circuit 18 is illustrated. However, this is for simplified illustration, and a plurality of lighting circuits 18, for example, may be configured for respective heating groups.

The lighting circuit 18 is electrically connected to the light sources 12 such that an identical level of electricity is supplied to a plurality of the light sources 12 belonging to each heating group. FIG. 1 shows a position at which the controller 15 is disposed of. However, this is for schematic illustration and should not be construed to limit where the controller 15 is disposed of.

In the present embodiment, the auxiliary light source S1 is disposed in a center area of the processing target substrate 10. The controller may control electricity supplied to the auxiliary light source S1 separately from that supplied to other heating groups. A level of electricity different from that supplied to the heating groups may be supplied to the auxiliary light source S1. Moreover, the auxiliary light source S1 may be configured to be controlled in common with another heating group. For instance, the auxiliary light source S1 may be connected to a lighting circuit 18 shared with the 12th heating group G12 and may be controlled in a similar way to the 12th heating group G12. Alternatively, a lighting circuit 18 that supplies electricity to the auxiliary light source S1 may be configured individually, and a level of electricity common to the light sources 12 belonging to the 12th heating group G12 may be supplied to the auxiliary light source S1.

### (Verification)

Results of heating conditions simulated for the processing target substrate 10 when electricity supplied to the heating groups is controlled will now be described.

This verification was conducted on condition that the processing target substrate 10 subject to heating had a diameter of 300 mm and a thickness of 0.775 mm. The light source unit 11 had a configuration that is described above with reference to FIGS. 3A to 3D. The distance between the processing target substrate 10 and an end face on the +Z side of the light guide member 13 included in the light source unit 11 was 20 mm. The processing target substrate 10 was rotated at a rate of 100 rpm.

Table 2 shows control patterns simulated in this verification. The table shows an example of individually controlled electricity supplied to each heating group. In Table 2, a relative proportion of levels of electricity supplied to the respective heating groups according to each control pattern is shown.

TABLE 2

| (%) | G1 | G2 | G3 | G4 | G5 | G6 | G7 | G8 | G9 | G10 | G11 | G12 | S1 |
|---|---|---|---|---|---|---|---|---|---|---|---|---|---|
| Control Pattern P1 | 100 | 60 | 65 | 30 | 30 | 40 | 50 | 30 | 30 | 30 | 50 | 50 | 50 |
| Control Pattern P2 | 50 | 50 | 50 | 50 | 50 | 50 | 50 | 50 | 50 | 50 | 50 | 100 | 100 |

As described later, a control pattern P1 is intended to heat preferentially the circumferential end side, i.e., an area on the external side in the radial direction, of the processing target substrate 10 compared with the other area. Thus, in the control pattern P1, a level of electricity input to the light sources 12 belonging to the first heating group G1 is a point of reference. A control pattern P2 is intended to heat preferentially the center side, i.e., an area on the internal side in the radial direction, of the processing target substrate 10 compared with the other area. Thus, in the control pattern P2, a level of electricity input to the light sources 12 belonging to the 12th heating group G12 is a point of reference.

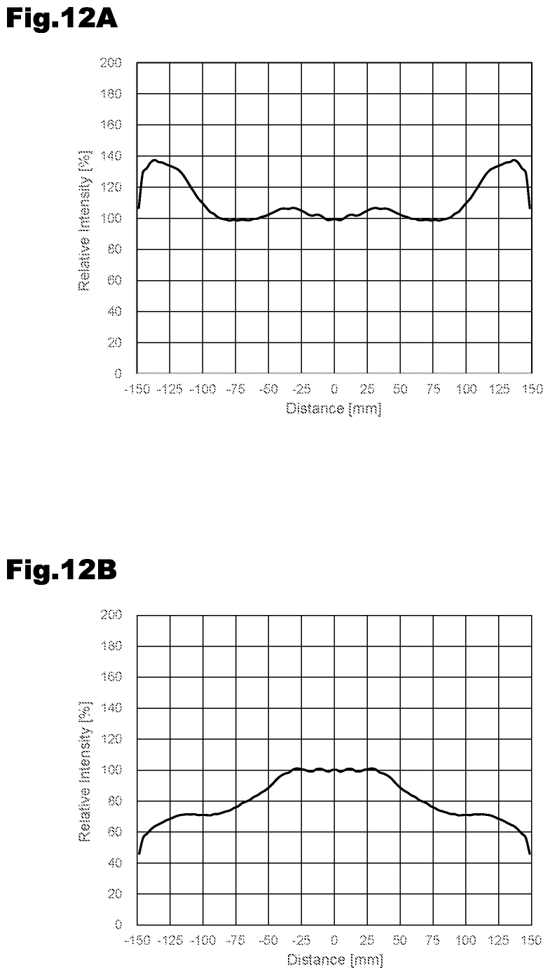

FIG. 12A is a graph of a heating condition simulated for the processing target substrate 10 on condition that electricity supplied to the heating groups is controlled based on the control pattern P1 shown in Table 2. In FIG. 12A, the horizontal axis represents distance in the radial direction with the center of the processing target substrate 10 set as a reference, whereas the vertical axis represents relative intensity of irradiance of the heating light L1 radiated to the processing target substrate 10. The relative intensity is shown with the irradiance at the center of the processing target substrate 10 set as a reference. As shown in FIG. 12A, based on the control pattern P1, the light source unit is designed to heat preferentially the area on the external side of the processing target substrate 10 in the radial direction compared with the other area. If there is a noticeable fall in temperature in a circumferential end area of the processing target substrate 10, for example, the light source unit is able to use the control pattern P1 and make the temperature in the first main surface 10a of the processing target substrate 10 uniform.

Following the example of FIG. 12A, FIG. 12B is a graph of a heating condition simulated for the processing target substrate 10 on condition that electricity supplied to the heating groups is controlled based on the control pattern P2 shown in Table 2. As shown in FIG. 12B, based on the control pattern P2, the light source unit is designed to heat preferentially the area on the internal side of the processing target substrate 10 in the radial direction compared with the other area. If there is a noticeable fall in temperature in the area on the internal side of the processing target substrate 10, for example, in a process for supplying a treatment solution to the center of the processing target substrate 10 to treat the second main surface 10b of the processing target substrate 10, the light source unit is able to use the control pattern P2 and make the temperature of the processing target substrate 10 uniform.

The optical heating apparatus 1 according to the present invention allows a larger number of the heating groups to be arranged in the radial direction of the processing target substrate 10 being rotated compared with conventional apparatuses. This allows high flexibility in setting a heating condition for the processing target substrate 10. Although the heating conditions for the processing target substrate 10 shown in FIGS. 12A and 12B are merely examples, a heating condition for the processing target substrate 10 can be designed in this way by adjusting electricity supplied to the light sources 12 belonging to each heating group.

### Modifications

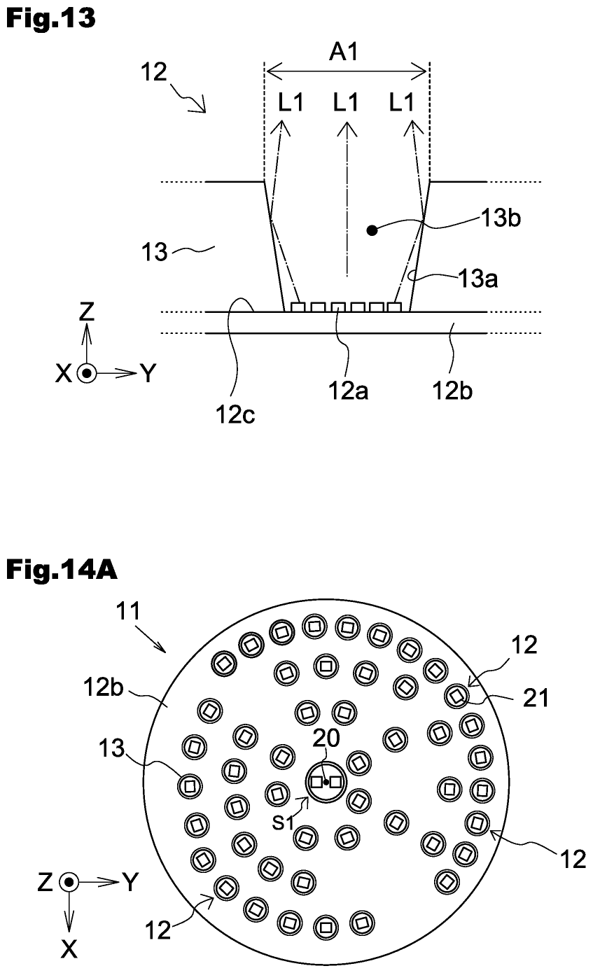

Modifications of the optical heating apparatus 1 will now be described.

<1> FIG. 13 is a cross-sectional view showing another example of the through-hole 13b provided in the light guide member 13, following the example of FIG. 3B. As shown in FIG. 13, the through-hole 13b may be formed such that an inner diameter of the through-hole 13b increases with progress in the +Z direction. This makes the reflecting surface 13a incline relative to the +Z direction and thus makes it possible to reduce an incidence angle at which the heating light L1 reflected off the reflecting surface 13a is incident on the first main surface 10a of the processing target substrate 10.

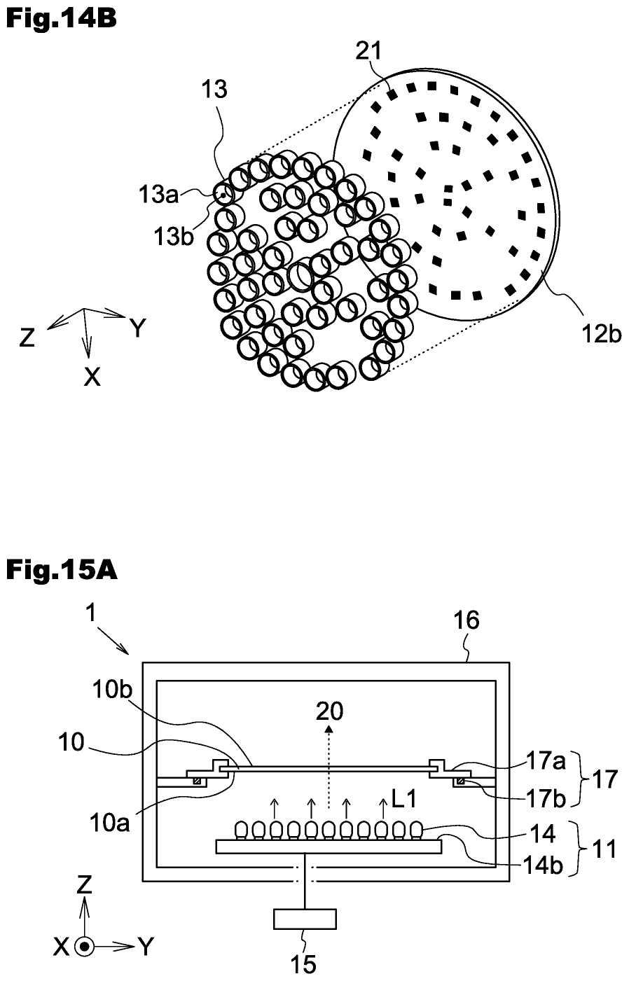

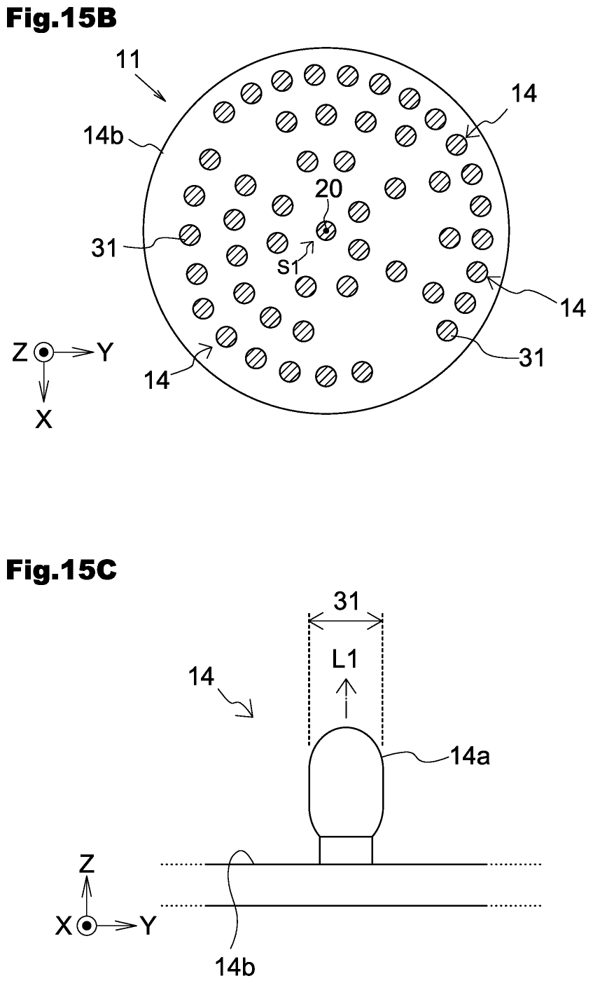

In other words, this improves directionality of the heating light L1 and increases the heating light L1 radiated to the first main surface 10a. This makes it possible to irradiate the processing target substrate 10 with the heating light L1 with increased efficiency.

<2> In the embodiment described above, the light guide member 13 is a plate in which the through-holes 13b are provided, for example. However, the light guide member 13 may be formed by providing through-holes 13b in a plate-shaped member made of any other material and attaching a sheet reflecting heating light L1 to or forming a reflective film reflecting heating light L1 on the inner surface of each of the through-holes 13b. The sheet may be made of, for example, a metal such as aluminum, aurum, copper, or rhodium. Alternatively, the reflective film may be formed with a metal similar to the metal for the sheet.

<3> FIGS. 14A and 14B are each a schematic view showing an example of another configuration of the light guide member 13, following the examples of FIGS. 3A and 3C. As shown in FIGS. 14A and 14B, tubular members may be installed as light guide members 13 so as to correspond to respective light sources 12. Each of the tubular members has a through-hole 13b, and an inner surface of the through-hole 13b is a reflecting surface 13a designed to reflect the heating light L1. According to this configuration, the light guide member 13 of one of the light sources 12 is disposed so as to be separated from the light guide member 13 of an other of the light sources 12. A material that the light guide members 13 are made of is the same as the material that is described above with reference to FIG. 3C.

<4> Unlike with the embodiment described above, the light source 12 may be constituted by a lamp. FIG. 15A is a schematic cross-sectional side view of a modification of the optical heating apparatus 1. FIG. 15B is a drawing of a light source unit 11 as viewed from the first main surface 10a of the processing target substrate 10 in the −Z direction, following the example of FIG. 3A. In FIG. 15B, the light emission regions 31 for lamps 14 are hatched by solid lines. FIG. 15C is an enlarged cross-sectional view showing the lamp 14.

As shown in FIG. 15C, one end of the lamp 14 is attached to an attachment surface 14b facing the first main surface 10a of the processing target substrate 10, and the lamp 14 irradiates the first main surface 10a with heating light L1. At this time, while diverging at a certain divergence angle, the heating light L1 travels in a direction (the Z direction) in which the processing target substrate 10 and the light source 12 face each other. In other words, as shown in FIG. 15C, for the light source 12 constituted by the lamp 14, the “light emission region 31” corresponds to an area of a light-emitting tube 14a of the lamp 14 as the light source unit 11 is viewed from the first main surface 10a of the processing target substrate 10 (refer to FIG. 15B as well).

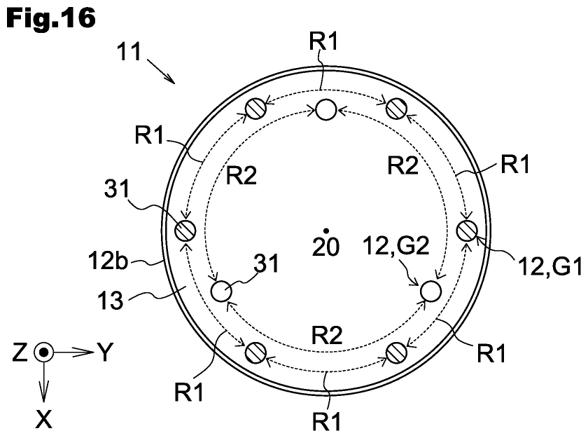

In a similar way to the light sources described above with reference to FIGS. 4A and 4B, the lamps 14 are organized into a plurality of heating groups (G1 to G12) according to distance from the rotation axis 20. The light emission region 31 for the lamp 14 in a heating group draws a rotation locus when being virtually rotated around the rotation axis 20, and the rotation locus by the heating group overlaps the rotation locus of the light emission region 31 for the lamp 14 in another heating group that is adjacent to the heating group and nearer to the rotation axis 20. This point is shared by the embodiment described above.

<5> FIG. 16 is a schematic view showing another example of arranged light sources 12 in a light source unit 11. As shown in FIG. 16, the light sources 12 belonging to the first heating group G1 may be arranged, for example, such that the adjacent light sources 12 in the first heating group G1 are at equal intervals of distance R1. Further, the light sources 12 belonging to the second heating group G2 may be arranged such that the adjacent light sources 12 in the second heating group are at equal intervals of distance R2. In FIG. 16, the light sources 12 belonging to the first heating group G1 are hatched. The same applies to the other heating groups although illustration of the third heating group G3 and subsequent heating groups is omitted.

In FIG. 16, the light sources 12 belonging to the second heating group G2 are arranged between the light sources 12 belonging to the first heating group G1 in the circumferential direction. The description given with reference to FIGS. 9A and 9B can be similarly given to this point.

<6> As shown in the embodiment described above, an auxiliary light source S1 may be disposed from the viewpoint of making a supplementary adjustment to the heating condition for the processing target substrate 10. The auxiliary light source S1 may have any size, may be disposed at any place, and other conditions such as what number of pieces are disposed may be freely decided. For instance, the auxiliary light source S1 that has a size different from the size of other light sources 12 making up each heating group may be disposed so as to overlap the area of the first rotation locus A1. While a level of electricity equal to or less than that supplied to the light source 12 that is near to the auxiliary light source S1 in the radial direction is typically supplied to the auxiliary light source S1, any level of electricity may be supplied to the auxiliary light source S1.

<7> In the embodiment described above (refer to FIG. 1 and others), the light source unit 11 is disposed inside the chamber 16. However, the light source unit 11 may be disposed outside the chamber 16 and may be designed, for example, to irradiate the processing target substrate 10 with heating light L1 from outside the chamber 16 through a light transmission window included in the chamber 16.

<8> In the embodiment described above, the processing target substrate 10 is rotated relative to the light source unit 11, for example. However, the light source unit 11 may be rotated relative to the processing target substrate 10.

<9> Furthermore, in the embodiment described above, the light sources 12 are arranged at identical places in the Z direction. However, the light sources 12 in different heating groups may be arranged at different places in the Z direction.

<10> The configurations of the optical heating apparatus 1 described above are merely examples, and the scope of the present invention is not limited to the illustrated configurations.

### DESCRIPTION OF REFERENCE SIGNS

1 optical heating apparatus
10 processing target substrate
10a first main surface
10b second main surface
11 light source unit
12 light source
12a LED device
12b LED substrate
12c placement surface
13 light guide member
13a reflecting surface
13b through-hole
14 lamp
15 controller
16 chamber
17 supporter
17a clamp
17b rotation rail
18 lighting circuit
19 processor
19a control signal
20 rotation axis
21 disposition region
31 light emission region
32 overlapping area
41, 44 circle
42, 45 circular arc
A1, A2, An rotation locus
G1-G12 heating group
S1 auxiliary light source

1. An optical heating apparatus comprising:
a chamber to accommodate a processing target substrate that is subject to heating;
a supporter to support the processing target substrate inside the chamber;
a light source unit including a plurality of heating groups arranged so as to face a main surface of the processing target substrate supported by the supporter, the plurality of the heating groups being configured to emit light for heating to the main surface; and
a controller to control electricity supplied to each of the plurality of the heating groups,
wherein one of the processing target substrate and the light source unit is configured to rotate relative to an other of the processing target substrate and the light source unit on a rotation axis passing through the main surface of the processing target substrate in a direction of normal to the main surface,
the plurality of the heating groups each include a plurality of light sources that are at a substantially identical distance from the rotation axis, and
an nth circular rotation locus drawn by virtually rotation of a light emission region of each of the light sources belonging to an nth heating group around the rotation axis and an (n+1)th circular rotation locus drawn by virtually rotation of a light emission region of each of the light sources belonging to an (n+1)th heating group that is nearer to the rotation axis than the nth heating group around the rotation axis partially overlap each other as viewed along the rotation axis.

2. The optical heating apparatus according to claim 1, wherein an overlapping area where the nth circular rotation locus and the (n+1)th circular rotation locus overlap each other as viewed along the rotation axis accounts for at least 50% of an area of the (n+1)th circular rotation locus.

3. The optical heating apparatus according to claim 1, wherein a number of the light sources belonging to the nth heating group is greater than or equal to a number of the light sources belonging to the (n+1)th heating group.

4. The optical heating apparatus according to claim 1, wherein the light sources belonging to the (n+1)th heating group are arranged between the light sources belonging to the nth heating group in a circumferential direction of a circle centered on the rotation axis.

5. The optical heating apparatus according to claim 4, wherein all the light sources belonging to the (n+1)th heating group are arranged consecutively between the light sources belonging to the nth heating group in the circumferential direction of the circle centered on the rotation axis.

6. The optical heating apparatus according to claim 1, wherein the nth heating group and the (n+1)th heating group each include a plurality of the light sources arranged unevenly on a circumference of a circle centered on the rotation axis.

7. The optical heating apparatus according to claim 1, wherein the plurality of the light sources have a light guide member to guide the light for heating being emitted from each of the light sources and traveling in a direction that is not aimed at the processing target substrate into a path toward the processing target substrate.

8. The optical heating apparatus according to claim 1, wherein the plurality of the light sources each comprise:
a plurality of LED devices; and
a light guide member that surrounds the plurality of the LED devices as viewed along the rotation axis, the light guide member being configured to guide the light for heating being emitted from each of the light sources and traveling in a direction that is not aimed at the processing target substrate into a path toward the processing target substrate.

9. The optical heating apparatus according to claim 8, wherein the light guide member of one of the plurality of the light sources is disposed so as to be separated from the light guide member of an other of the plurality of the light sources.

10. The optical heating apparatus according to claim 8, wherein the plurality of the light sources have a substantially common arrangement of the plurality of the LED devices and a substantially common shape of the light guide member.

11. The optical heating apparatus according to claim 8, wherein the light source unit includes an auxiliary light source disposed on the rotation axis, and
the auxiliary light source has a larger number of the LED devices than the plurality of the light sources each have.

12. A light source unit for use in the optical heating apparatus according to claim 1.
